(19) United States
(12) Patent Application Publication
(10) Pub. No.: US 2026/0164755 A1
(43) Pub. Date: Jun. 11, 2026

(54) FIELD EFFECT TRANSISTOR

(71) Applicant: STMicroelectronics International N.V., Geneva (CH)

(72) Inventors: Antonin Chollet, Rousset (FR); Julien Dura, Peypin (FR); Stephane Monfray, Eybens (FR)

(21) Appl. No.: 19/409,338

(22) Filed: Dec. 4, 2025

(30) Foreign Application Priority Data
Dec. 5, 2024 (FR) FR2413522

(51) Int. Cl. H10D 64/66; H10D 30/01; H10D 64/27

(52) U.S. Cl. CPC H10D 64/662; H10D 30/027; H10D 64/518; H10D 64/679

(57) ABSTRACT

The present description concerns a transistor comprising a gate insulator, a conductive gate, the conductive gate comprises a lower portion and an upper portion, the lower portion of the conductive gate having a length shorter than the length of the upper portion of the conductive gate, a first spacer and a second spacer, the first spacer and the second spacer each cover a flank of the upper portion of the conductive gate, and a first cavity and a second cavity, the first cavity is arranged between the upper portion of the conductive gate, the first spacer, and the gate insulator, and the second cavity is arranged between the upper portion of the conductive gate, the second spacer and the gate insulator, wherein the first spacer and the second spacer are separated from respective flanks of the lower portion of the conductive gate by the first cavity and the second cavity.

### CROSS-REFERENCE TO RELATED APPLICATIONS

This application claims the benefit of France Application No. 2413522, filed on Dec. 5, 2024, which application is hereby incorporated herein by reference.

### TECHNICAL FIELD

The present disclosure generally concerns electronic components and more particularly field-effect transistors of MOSFET (Metal Oxide Semiconductor Field Effect Transistor) type.

### BACKGROUND

MOSFET-type transistors are field-effect transistors comprising a conductive gate electrically insulated from a semiconductor layer by a dielectric layer known as the gate insulator. Various designs of MOSFET transistors have already been provided.

### SUMMARY

Improvements, to the electrical performance of MOSFET transistors intended for radio frequency (RF) signal switching applications, also known as RF switches, is more particularly considered herein.

An embodiment provides a transistor, on a semiconductor layer, comprising: a gate insulator, a conductive gate, wherein the conductive gate is arranged over and in contact with the gate insulator, wherein the conductive gate comprises a lower portion and an upper portion, the lower portion of the conductive gate having a length shorter than the length of the upper portion of the conductive gate, a first spacer and a second spacer, wherein the first spacer and the second spacer each cover a flank of the upper portion of the conductive gate, and a first cavity and a second cavity, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity.

According to an embodiment, the first cavity and the second cavity are each filled with a gas or with vacuum.

According to an embodiment, the cavities have a width in the range from 5 nm to 30 nm.

According to an embodiment, the cavities have a height in the range from 5 nm to 50 nm.

According to an embodiment, the upper portion of the conductive gate and the lower portion of the conductive gate are made of the same material.

According to an embodiment, the material is polysilicon.

According to an embodiment, the upper portion of the conductive gate and the lower portion of the conductive gate are made of two different materials.

According to an embodiment, the upper portion of the conductive gate is made of polysilicon and the lower portion of the conductive gate is made of silicon-germanium.

According an embodiment, the semiconductor layer corresponds to a silicon substrate or to a silicon layer of a silicon-on-insulator substrate.

Another embodiment provides a method of manufacturing a transistor, the method comprising: forming, on a semiconductor layer, of a stack of a gate insulator and of a conductive gate, the conductive gate being formed over and in contact with the gate insulator, the conductive gate comprising a lower portion and an upper portion, the lower portion of the conductive gate having a length shorter than the length of the upper portion of the conductive gate, and forming a first spacer and a second spacer that each cover a flank of the upper portion of the conductive gate, wherein the forming of the first spacer and the second spacer defines a first cavity and a second cavity, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity

According to an embodiment, the first cavity and the second cavity are each filled with a gas or with vacuum.

According to an embodiment, the forming of the conductive gate comprises the deposition of a layer of the conductive gate and in its etching.

According to an embodiment, the lower portion of the conductive gate and the upper portion of the conductive gate are made of the same material and the conductive gate is formed in a single step.

According to an embodiment, the etching of the conductive gate is an anisotropic etching.

According to an embodiment, the lower portion of the conductive gate and the upper portion of the conductive gate are made of two different materials, wherein the forming of the conductive gate comprises a first step of forming of the lower portion of the conductive gate over and in contact with the gate insulator and a second step of forming of the upper portion of the conductive gate over and in contact with the lower portion of the conductive layer.

According to an embodiment, the etching of the conductive gate comprises an anisotropic etching of the upper portion of the conductive gate and an isotropic etching of the lower portion of the conductive gate.

According to an embodiment, the spacers are formed by a non-conformal deposition method.

Another embodiment provides, a transistor, on a semiconductor layer, comprising: a gate insulator, a conductive gate, wherein the conductive gate is arranged over and in contact with the gate insulator, wherein the conductive gate comprises a lower portion and an upper portion, the lower portion of the conductive gate having a length shorter than the length of the upper portion of the conductive gate, a first spacer and a second spacer that each cover a flank of the upper portion of the conductive gate, wherein the first cavity and the second cavity are each filled with a gas or with vacuum, and a first cavity and a second cavity having a width in the range from 5 nm to 30 nm and a height in the range from 5 nm to 50 nm, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity.

According to an embodiment, the upper portion of the conductive gate and the lower portion of the conductive gate are made of the same material.

According to an embodiment, the material is polysilicon.

According to an embodiment, the upper portion of the conductive gate and the lower portion of the conductive gate are made of two different materials.

According to an embodiment, the upper portion of the conductive gate is made of polysilicon and the lower portion of the conductive gate is made of silicon-germanium.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of a transistor according to a first embodiment;

FIG. 2A, FIG. 2B, FIG. 2C, FIG. 2D, and FIG. 2E are cross-section views, partial and simplified, of structures obtained at the end of successive steps of an example of a method of manufacturing the transistor of FIG. 1;

FIG. 3 is a cross-section view, partial and simplified, of an example of a transistor according to a second embodiment; and

FIG. 4A, FIG. 4B, FIG. 4C, FIG. 4D, FIG. 4E, and FIG. 4F are cross-section views, partial and simplified, of structures obtained at the end of successive steps of an example of a method of manufacturing the transistor of FIG. 3.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the various possible applications of the described transistors have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

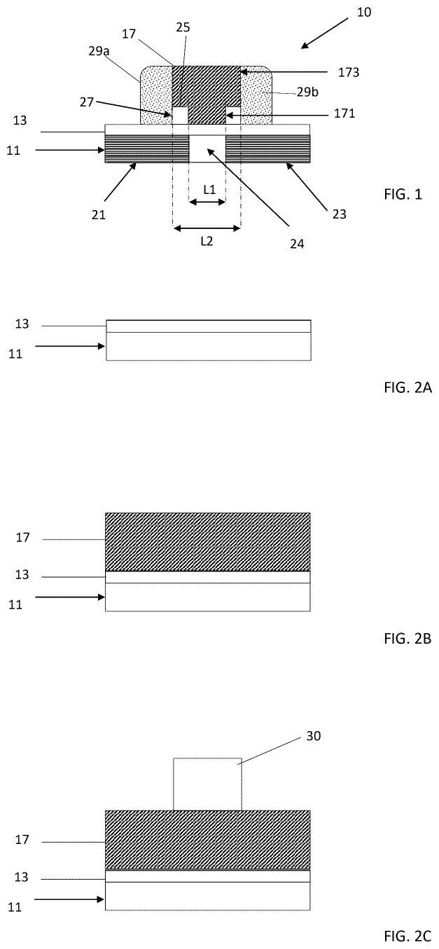

FIG. 1 is a cross-section view, partial and simplified, of an example of a transistor 10 according to a first embodiment.

Transistor 10 comprises a semiconductor layer 11 topped with a dielectric layer 13, also called gate insulator.

In some implementations, the semiconductor layer 11 is made of silicon. For example, the semiconductor layer 11 can be made of single-crystal silicon. In some implementations, the semiconductor layer 11 may correspond to a silicon substrate. In other implementations, the semiconductor layer 11 may correspond to the upper silicon layer of a silicon-on-insulator (SOI) substrate. In some implementations, the semiconductor layer 11 may have a thickness that ranges from 10 nm to 500 nm. For example, the semiconductor layer 11 may have a thickness in the range from 50 nm to 200 nm. By way of another example, the semiconductor 11 may have a thickness of 70 nm.

In some implementations, gate insulator 13 is made of silicon dioxide (SiO2). In some implementations, gate insulator 13 may have a thickness in the range from 1 nm to 15 nm. For example, the gate insulator may have thickness in the range from 3 nm to 7 nm.

The gate insulator 13 can be arranged proximate to the semiconductor later 11. In some implementations, for example, the gate insulator 13 is arranged over and in contact with semiconductor layer 11.

Transistor 10 further comprises a conductive layer 17, which is also referred to here as a conductive gate, on gate insulator layer 13. The conductive gate 17 is arranged over and in contact with gate insulator 13.

In this embodiment, conductive gate 17 comprises a lower portion 171 and an upper portion 173, the upper portion 173 being arranged over and in contact with the lower portion 171 and the lower portion 171 being formed over and in contact with gate insulator 13.

In FIG. 1, the lower portion 171 of conductive gate 17 has a length L1 shorter than the length L2 of the upper portion 173 of conductive gate 17. Thus, the conductive gate has a length shorter on its lower surface side, that is, on the side of gate insulator 13.

In some implementations, length L1 is constant over the entire height of the lower portion 171 of gate 17. In some implementations, length L2 is constant over the entire height of the upper portion 173 of gate 17.

In some implementations, the upper portion 173 of conductive gate 17 is arranged on the surface of the lower portion 171, centered thereon.

Conductive gate 17 thus comprises across its entire width notches 25, exposing a portion of the upper surface of gate insulator 13. As an example, gate 17 comprises two notches 25, each formed on either side of gate 17.

In the embodiment of FIG. 1, conductive gate 17 is made of doped polysilicon.

In some implementations, length L2 is in the range from 50 nm to 300 nm. For example, the length L2 can be in the range from 80 nm to 200 nm. By way of another example, the length L2 can be 100 nm. In some implementations, portions 171 and 173 of conductive gate layer 17 may have a length difference in the range from 10 nm to 60 nm. For example, the portions 171 and 173 of conductive gate layer 17 may have a length difference of 20 nm. In some implementations, notches 25 may each have a width (taken in the cross-section plane of FIG. 1) in the range from 5 nm to 30 nm. For example, the notches 25 may each have a width of 10 nm.

In some implementations, conductive gate 17 may have a width in the range from 1 μm to 10 μm. For example, the conductive gate 17 may have a width of 5 μm.

In some implementations, layer 17 may have a thickness in the range from 30 nm to 300 nm. For example, the layer 17 may have a thickness in the range from 50 nm to 150 nm. By way of another example, the layer 17 may have thickness of 120 nm.

In some implementations, lower portion 171 may have a thickness in the range from 2.5 nm to 50 nm. For example, the lower portion 171 may have a thickness 10 nm.

Transistor 10 comprises, for example, a source region 21 and a drain region 23 formed in semiconductor layer 11. In some implementations, source region 21 and drain region 23 may be laterally separated from each other by a body region. An upper portion of the body region forms the channel-forming region 24 of transistor 10. In some implementations, conductive gate layer 17 may be located above channel-forming region 24.

In some implementations, the source 21, drain 23, and body regions may be flush with the upper surface of semiconductor layer 11.

In some implementations, transistor 10 may be an N-channel MOS (NMOS) transistor, that is, a transistor having source 21 and drain 23 regions which are N-type doped, while the body region is P-type doped. An region that is N-type doped may be doped with arsenic or phosphorus atoms. A region that is P-type doped may be doped with boron atoms.

In other implementations, transistor 10 may be a P-channel MOS (PMOS) transistor, that is, a transistor having source 21 and drain 23 regions which are P-doped, while the body region is N-doped. As indicated above, a region that is P-type doped is may be doped with boron atoms and a region that is N-type doped may be doped with arsenic or phosphorus atoms.

Transistor 10 further comprises two cavities 27 arranged on either side of the lower portion 171 of conductive gate 17 in notches 25. In some implementations, each of the two cavities 27 may be filled with a gas or with vacuum. Cavities 27 are arranged between the upper portion 173 of conductive gate 17 and gate insulator 13. In some implementations, cavities 27 do not extend beyond the location facing the upper portion 173 of conductive gate 17. In other implementations, cavities 27 extend across the entire width of gate 17.

In some implementations, the gas present in cavities 27 may comprise nitrogen, hydrogen bromide, tetraethyl orthosilicate (TEOS), bis(fluoroxy) perfluoromethane (CF4O2), argon, or any other gas resulting from chemical reactions occurring during the transistor manufacturing such as, for example, from reactions between silane (SiH4) and ammonia (NH3) and/or present in the atmosphere of the manufacturing equipment. In other implementations, cavities 27 may be filled with partial vacuum.

Transistor 10 further comprises spacers 29a, 29b, covering, on either side, the flanks of the upper portion 173 of conductive gate 17. In some implementations, transistor 10 comprises a first spacer 29a formed, on a first side of gate 17, on the lateral flanks of gate 17. In such implementations, the transistor 10 may further comprise a second spacer 29b formed, on a second side of gate 17, opposite to the first side with respect to the length of gate 17, on the lateral flanks of gate 17. The spacers are, for example, laterally in contact with the flanks of the upper portion 173 of conductive gate 17.

In this embodiment, spacers 29a, 29b extend opposite the flanks of the lower portion 171 of conductive gate 17. As an example, spacers 29a, 29b are in contact, by their lower surface, with the upper surface of gate insulator layer 13. Each spacer 29a, 29b is spaced apart from the flank of the lower portion 171 of conductive gate 17 that it covers by a cavity 27.

Spacers 29a, 29b extend, for example, across the entire width of gate 17.

In the embodiment shown in FIG. 1, spacers 29a, 29b are “D”-shaped, with a substantially planar lower surface.

As a variant, spacers 29a, 29b may have an “L” shape, having its vertical part lining the side flanks of the upper portion of gate 17 and the side flanks of cavities 27, and having its horizontal part lining the upper surface of gate insulator 13.

In some implementation, spacers 29a, 29b are for example made of an insulating material, for example of silicon nitride (Si3N4), tungsten carbide, silicon carbide, aluminum oxide, beryllium oxide, magnesium oxide, zirconium oxide, silicon, aluminum silicate, silicon oxide, borophosphosilicate glass, borosilicate glass, phosphosilicate glass, fluorosilicate glass, undoped silicate glass, and/or hexagonal boron nitride (hBN).

In some implementations, transistor 10 comprises an insulating layer, not shown, arranged over and in contact with the flanks of conductive gate 17. The insulating layer can be made of, for example, oxide or nitride. For example, in some implementations, the insulating layer may be made of silicon nitride (Si3N4). In some implementations, spacers 29a, 29b may be in contact with the insulating layer opposite the flanks of the upper portion 173 of gate 17.

In some implementations, transistors 10 may be RF switches that operate at frequencies in the range from 3 kHz to 300 GHz. For example, the transistors 10 may be RF switches that operate at frequences in the range from 100 MHz to 10 GHz. By way of another example, the transistors 10 may be RF switches that operate at one GHz. In such implementations, the transistors 109 may exhibit a low parasitic capacitance COFF in the off state of the transistor and a low resistance RON in the on state of the transistor are desired, while maintaining a good voltage behavior.

An advantage of the present embodiment is that the forming of cavities 27 enables a decrease in the length of the gate 17 that is in contact with gate insulator 13 and thus results in a decrease in the resistance RON of the switch.

Another advantage of the present embodiment is that the provision of cavities 27 in the lower portion of the gate enables a decrease in the capacitance COFF of the switch.

This embodiment thus enables an optimization of the RON and COFF trade-off for the RF switch.

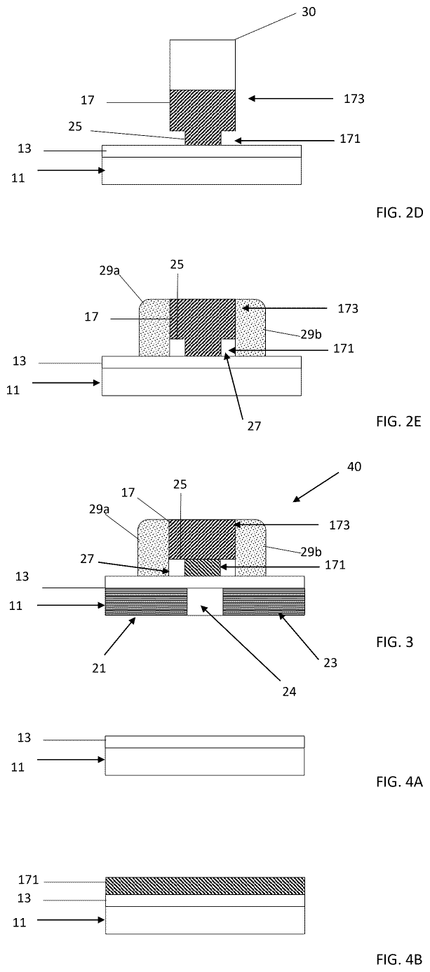

FIG. 2A, FIG. 2B, FIG. 2C, FIG. 2D, and FIG. 2E are cross-section views, partial and simplified, of structures obtained at the end of successive steps of an example of a method of manufacturing the transistor of FIG. 1.

FIG. 2A shows an initial structure comprising a stack of gate insulator layer 13 on the upper surface of semiconductor layer 11. In this example of FIG. 2A, the gate insulator layer 13 is in contact, by its lower surface, with the upper surface of semiconductor layer 11.

As shown in the initial structure of FIG. 2A, gate insulator layer 13 covers the entire upper surface of semiconductor layer 11. In some implementations, gate insulator layer 13 is formed at the surface of semiconductor layer 11 by oxidation of this same layer.

FIG. 2B illustrates a structure obtained at the end of a step of forming of conductive gate layer 17 on the upper surface of gate insulator layer 13. In some implementations, gate layer 17 may be formed by a diffusion furnace deposition process.

In other implementations, gate layer 17 may be deposited by a vapor deposition process such as, for example, a vapor epitaxy process.

FIG. 2C illustrates a structure obtained at the end of a step of forming of a resin masking layer 30 on the upper surface of the structure illustrated in FIG. 2B.

More particularly, during this step, masking layer 30 is formed in contact with the upper surface of gate layer 17. Mask layer 30 undergoes, after its deposition, a photolithography step, that is, it is locally exposed to rays, for example ultraviolet, and then rinsed. Mask layer 30 then corresponds, at the end of these steps, to an etch mask for the underlying layer 17.

The resin of mask layer 30 is for example resist, for example positive resist.

FIG. 2D illustrates a structure obtained at the end of a step of etching of conductive gate layer 17 from the structure shown in FIG. 2C.

In some implementations, conductive gate layer 17 is etched in a single etching operation, which may possibly comprise a plurality of steps. For example, the etching of gate 17 may comprise a dry etching such as, for example, a plasma chemical etching.

In some implementations, conductive gate layer 17 is etched in a single etching operation such as, for example, by modifying during etching the bias parameters, in order to form notch 25 in the lower portion 171 of gate layer 17. Alternatively, or in addition, the forming of notch 25 may comprise, after the etching of layer 17, a step of reoxidizing of a lower portion of the gate, followed by a step of removal of the reoxidized portion, for example by wet etching, for example based on hydrofluoric acid.

At the end of this step, resin layer 30 is for example removed from the upper surface of gate 17.

FIG. 2E illustrates a structure obtained at the end of a step of forming of spacers 29a, 29b on the upper surface of the structure illustrated in FIG. 2D.

As an example, spacers 29a, 29b are formed by a chemical vapor deposition process such as, for example, plasma-assisted.

Spacers 29a, 29b are non-conformally formed, that is, they are formed with a non-uniform thickness over the entire surface of the structure illustrated in FIG. 2D.

The non-conformality of the deposition enables the notches 25 formed in gate 17 to not be filled with the material of spacer 29a, 29b, thus trapping gas in notches 25 and forming cavities 27.

In some implementations, the gas trapped in cavities 27 corresponds to the precursor gas used during the deposition of spacers 29a, 29b.

In other implementations, the gas trapped in cavities 27 corresponds to the precursor gas used during the etching of gate 17.

In some implementations, the cavities 27 may have a cubic shape.

In other implementations, cavities 27 may have, in the cross-section plane of FIG. 2E, an L shape or a D shape. The shape of cavities 27 may depend on the filling capacity of notches 25. For example, if notches 25 are easily filled, then material of spacer 29a, 29b may tend to at least partially fill notches 25 and cavities 27 will be L-shaped. By way of another example, if notches 25 are not easy to fill, the material of spacer 29a, 29b may not tend to fill notches 25 and cavities 27 may have a cubic shape.

In some implementations, spacers 29a, 29b may be formed by a deposition of a layer made of the material of the spacers over the entire upper surface of the structure shown in FIG. 2D. In such implementations, at the end of the deposition of said layer, the latter is for example etched by anisotropic dry etching, so as to only be kept around gate 17 and form spacers 29a, 29b.

At the end of this step, the source 21 and drain 23 regions are for example formed in the structure shown in FIG. 2E, to form the transistor 10 shown in FIG. 1. As an example, the source 21 and drain 23 regions are formed by implantation of dopants into semiconductor layer 11.

FIG. 3 is a cross-section view, partial and simplified, of an example of a transistor 40 according to a second embodiment.

Transistor 40 is similar to transistor 10 with the difference that, in transistor 40, the lower portion 171 and the upper portion 173 of conductive gate 17 do not have the same natures.

In the embodiment of FIG. 3, the upper portion 173 of gate 17 is based on polysilicon

In the embodiment of FIG. 3, the lower portion 171 of gate 17 is based on germanium-doped polysilicon. As an example, the lower portion 171 of the gate has a germanium content in the range from 15% to 35%, for example in the order of 25% by mass.

As a variant, the lower portion 171 of gate layer 17 is made of a material different from silicon-germanium, having an etch rate higher than the etch rate of silicon. The lower portion 171 of gate layer 17 is for example made of silicon-germanium-carbon (SiGeC), of doped silicon-germanium (SiGe), comprising for example, as dopants, boron, phosphorus, or arsenic atoms.

An advantage of the present embodiment is that the silicon-germanium of the lower portion 171 of gate 17 improves the depletion of the polysilicon of the upper portion 173 of gate 17, that is, it enables to decrease the polydepletion zone, through a better activation of dopants enabling to decrease the threshold voltage.

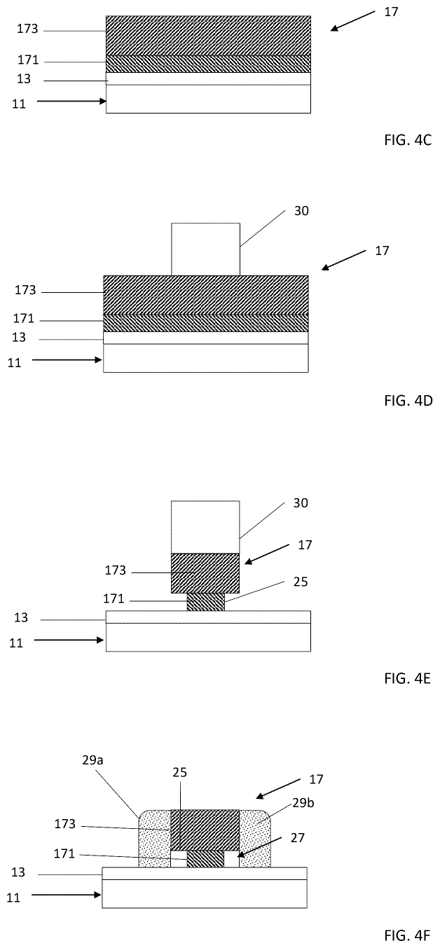

FIG. 4A, FIG. 4B, FIG. 4C, FIG. 4D, FIG. 4E, and FIG. 4F are cross-section views, partial and simplified, of structures obtained at the end of successive steps of an example of a method of manufacturing the transistor of FIG. 3.

This manufacturing method is similar to that described in relation to FIGS. 2A to 2E, with the difference that the lower and upper portions of gate 17 are made of different materials, which has an impact on their depositions and on the step of etching of gate 17.

FIG. 4A illustrates an initial step identical to that shown in FIG. 2A.

FIG. 4B illustrates a structure obtained at the end of a step of forming of the lower portion 171 of conductive gate layer 17 on the upper surface of gate insulator layer 13.

In some implementations, the lower portion 171 of conductive gate layer 17 is deposited by reduced pressure chemical vapor deposition or RPCVD.

The lower portion of conductive gate layer 17 may cover, for example, the entire upper surface of gate insulator 13. In some implementations, the lower portion 171 of conductive gate layer 17 is deposited with a thickness in the range from 5 nm to 100 nm. For example, the lower portion 171 of conductive gate layer 17 may be deposited with a thickness of 40 nm.

FIG. 4C illustrates a structure obtained at the end of a step of forming of the upper portion 173 of the conductive gate layer 17 on the upper surface of the lower portion 173 of conductive gate layer 17.

In some implementations, the upper portion 173 of conductive gate layer 17 is formed by a vapor deposition process such as, for example, a vapor epitaxy process.

In some implementations, the upper portion 173 of gate layer 17 is deposited in the same deposition chamber as the lower portion 171.

In other implementations, the deposition of the lower portion 171 and of the upper portion 173 of layer 17 are performed in two different deposition chambers. In some implementations, the upper portion 173 of layer 17 is deposited in a diffusion furnace.

In some implementations, the upper portion 173 of conductive gate layer 17 may cover the entire upper surface of the lower portion 171 of conductive gate layer 17. In some implementations, the upper portion 173 of conductive gate layer 17 is deposited with a thickness in the range from 25 nm to 250 nm. For example, the upper portion 173 of conductive gate layer 17 may be deposited with a thickness of 80 nm.

FIG. 4D illustrates a structure obtained at the end of a step of forming of a resin masking layer 30 on the upper surface of the structure shown in FIG. 4C.

The forming of masking layer 30 may be, for example, similar to what has been previously described in relation with FIG. 2C.

FIG. 4E shows a structure obtained at the end of a step of etching of conductive gate layer 17 from the structure shown in FIG. 4D.

In some implementations, the etching of gate 17 may comprise three successive etch steps.

In some implementations, the etching of gate 17 may comprise a step of anisotropic etching of the upper portion 173 of gate 17. In some implementations, this etch step may be selective so that only the upper portion 173 of gate 17 is etched.

During this step, the upper portion 173 of gate 17 may be etched so that, at the end of this step, the flanks of upper portion 173 are aligned with resin layer 30. In some implementations, the etching here is a dry etching.

In some implementations, the etching of gate 17 may further comprise a step of anisotropic etching of the lower portion 171 of gate 17. In some implementations, this etch step may be selective so that only the lower portion 171 of gate 17 is etched.

During this step, the lower portion 173 of gate layer 17 is etched so that, at the end of this step, the flanks of lower portion 171 are aligned with resin layer 30 and the upper portion 173 of gate layer 17. In some implementations, the etching here is dry etching.

In some implementations, the etching of gate 17 may further comprise a step of isotropic etching of the lower portion 171 of gate 17. In some implementations, this etch step may be selective so that only the lower portion 171 of gate 17 is etched.

During this step, the lower portion 171 of gate 17 is laterally etched, so as to create, under the upper portion 173 of gate layer 17, notches 25.

At the end of this step, a lower portion 171 is then arranged, under the upper portion 173 of gate 17, recessed with respect to the sides of the upper portion 173 of gate 17.

At the end of this step, the flanks of the upper portion 173 of gate layer 17 are aligned with resin layer 30. In some implementations, the etching here is a dry etching.

In some implementations, these three etch steps are plasma chemical etchings in which the nature of the species in the plasma, their content, the flow velocity, and the bias enable to define the anisotropic or isotropic nature of the etching and its selectivity.

In other implementations, the isotropic etching of the lower portion 171 is a wet etching.

In yet other implementations, the etching of the lower portion 171 of gate layer 17 may be carried out in a single isotropic etching operation, allowing at the same time the removal of the lower portion 171 from the location facing resin layer 30 and under a peripheral portion of resin layer 30.

FIG. 4F illustrates a structure obtained at the end of a step of forming of spacers 29a, 29b on the upper surface of the structure shown in FIG. 4E.

This step is identical to the step described in relation with FIG. 2E.

At the end of this step, the source 21 and drain 23 regions are formed, for example, in the structure shown in FIG. 4F so as to form the transistor 40 shown in FIG. 3. The step of forming of the source 21 and drain 23 regions is identical to that described at the end of the method described in FIGS. 2A to 2E.

An advantage of the second embodiment is that it enables to form cavities 27 in notches 25.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

What is claimed is:

1. A transistor, on a semiconductor layer, comprising:
a gate insulator;
a conductive gate, wherein the conductive gate is arranged over and in contact with the gate insulator, wherein the conductive gate comprises a lower portion and an upper portion, the lower portion of the conductive gate having a length shorter than the length of the upper portion of the conductive gate;
a first spacer and a second spacer, wherein the first spacer and the second spacer each cover a flank of the upper portion of the conductive gate; and
a first cavity and a second cavity, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity.

2. The transistor according to claim 1, wherein the first cavity and the second cavity are each filled with a gas or with vacuum.

3. The transistor according to claim 1, wherein the cavities have a width in a range from 5 nm to 30 nm.

4. The transistor according to claim 1, wherein the cavities have a height in a range from 5 nm to 50 nm.

5. The transistor according to claim 1, wherein the upper portion of the conductive gate and the lower portion of the conductive gate are made of the same material.

6. The transistor according to claim 5, wherein the material is polysilicon.

7. The transistor according to claim 1, wherein the upper portion of the conductive gate and the lower portion of the conductive gate are made of two different materials.

8. The transistor according to claim 7, wherein the upper portion of the conductive gate is made of polysilicon and the lower portion of the conductive gate is made of silicon-germanium.

9. The transistor according to claim 1, wherein the semiconductor layer corresponds to a silicon substrate or to a silicon layer of a silicon-on-insulator substrate.

10. A method of manufacturing a transistor, the method comprising:
forming, on a semiconductor layer, of a stack of a gate insulator and of a conductive gate, the conductive gate being formed over and in contact with the gate insulator, the conductive gate comprising a lower portion and an upper portion, the lower portion of the conductive gate having a length shorter than the length of the upper portion of the conductive gate; and
forming a first spacer and a second spacer that each cover a flank of the upper portion of the conductive gate, wherein the forming of the first spacer and the second spacer defines a first cavity and a second cavity, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity.

11. The method according to claim 10, wherein the first cavity and the second cavity are each filled with a gas or with vacuum.

12. The method according to claim 10, wherein the forming of the conductive gate comprises deposition of a layer of the conductive gate and in its etching.

13. The method according to claim 10, wherein the lower portion of the conductive gate and the upper portion of the conductive gate are made of the same material and the conductive gate is formed in a single step.

14. The method according to claim 12, wherein the etching of the conductive gate is an anisotropic etching.

15. The method according to claim 12, wherein the etching of the conductive gate is a plasma etching and wherein during the etching the bias of the plasma is modified.

16. The method according to claim 12, wherein the lower portion of the conductive gate and the upper portion of the conductive gate are made of two different materials, wherein the forming of the conductive gate comprises a first step of forming of the lower portion of the conductive gate over and in contact with the gate insulator and a second step of forming of the upper portion of the conductive gate over and in contact with the lower portion of the conductive layer.

17. The method according to claim 16, wherein the etching of the conductive gate comprises an anisotropic etching of the upper portion of the conductive gate and an isotropic etching of the lower portion of the conductive gate.

18. The method according to claim 10, wherein the spacers are formed by a non-conformal deposition method.

19. A transistor, on a semiconductor layer, comprising:
a gate insulator;
a conductive gate, wherein the conductive gate is arranged over and in contact with the gate insulator, wherein the conductive gate comprises a lower portion and an upper portion, the lower portion of the conductive gate having a length shorter than the length of the upper portion of the conductive gate;
a first spacer and a second spacer that each cover a flank of the upper portion of the conductive gate; and
a first cavity and a second cavity having a width in a range from 5 nm to 30 nm and a height in a range from 5 nm to 50 nm, the first cavity and the second cavity are each filled with a gas or with vacuum, wherein the first cavity is arranged between the upper portion of the conductive gate, the first spacer, and the gate insulator, and wherein the second cavity is arranged between the upper portion of the conductive gate, the second spacer and the gate insulator, wherein the first spacer and the second spacer are separated from respective flanks of the lower portion of the conductive gate by the first cavity and the second cavity.

20. The transistor according to claim 19, wherein the upper portion of the conductive gate and the lower portion of the conductive gate are made of two different materials.
